(19) United States
(12) Patent Application Publication
(10) Pub. No.: US 2025/0374480 A1
(43) Pub. Date: Dec. 4, 2025

(54) COOLER ASSEMBLY FOR ELECTRONIC MODULES

(71) Applicant: SEMICONDUCTOR COMPONENTS INDUSTRIES, LLC, Scottsdale, AZ (US)

(72) Inventors: Zhaoxi YAO, Lyman, ME (US); Yong LIU, Cumberland Foreside, ME (US)

(73) Assignee: SEMICONDUCTOR COMPONENTS INDUSTRIES, LLC, Scottsdale, AZ (US)

(21) Appl. No.: 18/732,248

(22) Filed: Jun. 3, 2024

(51) Int. Cl. H05K 7/20

(52) U.S. Cl. CPC H05K 7/20272; H05K 7/20254; H05K 7/20281

(57) ABSTRACT

An illustrative cooler assembly may include an inlet, an outlet, a cooling channel, and a distribution channel. The cooling channel may include an array of protrusions configured to transfer heat from a plurality of electronic modules to fluid flowing through the array of protrusions. The plurality of electronic modules may be disposed along a longitudinal axis extending between the inlet and the outlet. The distribution channel may be in fluid communication with the cooling channel via a venting system. The distribution channel may be configured to direct fluid entering at the inlet to flow through the cooling channel in a transverse direction substantially perpendicular to the longitudinal axis before exiting at the outlet. Corresponding systems, assemblies, and methods are also disclosed.

### TECHNICAL FIELD

This description relates to devices and methods of actively cooling electronic components such as power modules.

### BACKGROUND

Electronic devices and components are configured to operate properly only within certain temperature parameters. As a result, passive and/or active temperature control mechanisms may be used to help maintain the temperature within desired parameters as electronics operate. Certain types of electronics may be especially challenging to maintain within desired temperature ranges. As one example, electronic devices that consume or produce a large amount of power (e.g., power modules, processors, etc.) may tend to heat up significantly during operation and require significant cooling. As another example, electronic devices operating in certain environments (e.g., warm outdoor environments, enclosed environments with limited natural airflow, etc.) may also tend to be challenging to properly cool. While passive cooling involving various types of heatsinks and natural airflow may be suitable for cooling certain electronics, active cooling involving forced passage of gaseous or liquid coolants may be used in more challenging scenarios.

### SUMMARY

Cooler assemblies described herein may be used to actively cool electronic modules, which may be particularly useful in certain circumstances in which passive cooling may be insufficient. Multiple electronic modules may be installed collinearly along a longitudinal axis of a cooler assembly so that cooling fluid may be pumped through the cooler assembly in a manner that allows the electronic modules to transfer their heat to the fluid and remain within a desired temperature range. Rather than flowing along the longitudinal axis of the cooler to absorb heat from each electronic module in series, however, cooling fluid pumped through cooler assemblies described herein may be directed (e.g., by way of manifolds and heatsink mechanisms described herein) to flow in transverse directions substantially perpendicular to the longitudinal axis. As such, the fluid may absorb heat from the electronic modules substantially in parallel, rather than in series, and excellent temperature performance and uniformity may be achieved without compromising other parameters such as fluid pressure and/or the form factor of the cooler assembly.

In one example implementation, a cooler assembly may include an inlet, an outlet, a cooling channel, and a distribution channel. The cooling channel may include an array of protrusions configured to transfer heat from a plurality of electronic modules to fluid flowing through the array of protrusions. For instance, the plurality of electronic modules may be disposed along a longitudinal axis extending between the inlet and the outlet. The distribution channel may be in fluid communication with the cooling channel via a venting system and may be configured to direct fluid entering at the inlet to flow through the cooling channel in a transverse direction substantially perpendicular to the longitudinal axis before exiting at the outlet.

In one general aspect of this example implementation, the distribution channel may include a barrier between a supply side that includes the inlet and a return side that includes the outlet. The venting system may include a supply vent network on the supply side of the barrier and a return vent network on the return side of the barrier, the supply vent network and the return vent network each extending a distance along the longitudinal axis that spans the plurality of electronic modules. The barrier may be configured to direct fluid entering the inlet to flow to the outlet via the supply vent network, the cooling channel, and the return vent network. Additionally, a plurality of vents from the supply vent network and from the return vent network may be interleaved such that the barrier between the supply side and the return side extends back and forth along the longitudinal axis in a zigzag pattern.

In another general aspect of this example implementation, the distribution channel may be configured to direct fluid to simultaneously flow through the cooling channel in both the transverse direction and in an additional transverse direction substantially perpendicular to the longitudinal axis and substantially opposite the transverse direction.

In another general aspect of this example implementation, the distribution channel may include: 1) a barrier between a supply side that includes the inlet and a return side that includes the outlet, and 2) a set of flow control features on the return side of the barrier, the set of flow control features each configured to resist flow of fluid. In this aspect, the plurality of electronic modules may include a first electronic module and a second electronic module each warranting a same amount of cooling, and the set of flow control features may be arranged to direct fluid to flow at an equivalent flow rate for the first electronic module and for the second electronic module. Additionally or alternatively, the plurality of electronic modules may include a first electronic module and a second electronic module, the second electronic module warranting a different amount of cooling as the first electronic module; and the set of flow control features may be arranged to direct fluid to flow at different (customized) flow rates for the first electronic module and for the second electronic module.

In another general aspect of this example implementation, the venting system may include a plurality of discrete slots disposed along the longitudinal axis and each aligned to the longitudinal axis.

In another general aspect of this example implementation, the array of protrusions may include a series of planar fins disposed along the longitudinal axis and each aligned perpendicularly to the longitudinal axis to disallow flow of fluid along the longitudinal axis while allowing flow of fluid in the transverse direction.

In another general aspect of this example implementation, the array of protrusions may include an array of discrete protrusions configured to allow flow of fluid along the longitudinal axis and in the transverse direction. In this aspect, each discrete protrusion of the array of discrete protrusions may have a rectangular shape, a rounded shape, or a wavy shape, and the array of discrete protrusions may be arranged in a grid pattern or a staggered grid pattern.

In another general aspect of this example implementation, the cooler assembly may be associated with a first pressure parameter and a first temperature parameter that respectively meet or improve upon a second pressure parameter and a second temperature parameter of a legacy cooler assembly. As such, the cooler assembly may be associated with a form factor equivalent to the legacy cooler assembly so as to function as a drop-in replacement for the legacy cooler assembly.

In another general aspect of this example implementation, the plurality of electronic modules may include power electronics for a plurality of phases of a direct-current (DC) to alternating-current (AC) conversion circuit configured for use in an electric vehicle drivetrain.

In another example implementation, a cooler assembly may include a frame structure including an inlet and an outlet, a cooler plate coupled to the frame structure, and a manifold plate coupled to the frame structure. The cooler plate may include a module side and a heatsink side, the module side being configured to host a plurality of electronic modules disposed along a longitudinal axis extending between the inlet and the outlet, and the heatsink side including an array of protrusions configured to transfer heat from the plurality of electronic modules to fluid flowing through the array of protrusions. The manifold plate may include a cooling side and a distribution side connected via a venting system that allows fluid communication through the manifold plate, the cooling side being coupled to the array of protrusions and the distribution side being configured to direct fluid entering the inlet to flow through the array of protrusions in a transverse direction that is substantially perpendicular to the longitudinal axis before exiting the outlet.

In a general aspect of this example implementation, the distribution side of the manifold plate may include a barrier between a supply side that includes the inlet and a return side that includes the outlet. The venting system may include a supply vent network on the supply side of the barrier and a return vent network on the return side of the barrier, the supply vent network and the return vent network each extending a distance along the longitudinal axis that spans the plurality of electronic modules. The barrier may be configured to direct fluid entering the inlet to flow to the outlet via the supply vent network, the array of protrusions, and the return vent network. Additionally, a plurality of vents from the supply vent network and from the return vent network may be interleaved such that the barrier between the supply side and the return side extends back and forth along the longitudinal axis in a zigzag pattern.

In another general aspect of this example implementation, the distribution side of the manifold plate may be configured to direct fluid to simultaneously flow through the array of protrusions in both the transverse direction and in an additional transverse direction substantially perpendicular to the longitudinal axis and substantially opposite the transverse direction.

In another general aspect of this example implementation, the distribution side of the manifold plate may include: 1) a barrier between a supply side that includes the inlet and a return side that includes the outlet; and 2) a set of flow control features on the return side of the barrier, the set of flow control features each configured to resist flow of fluid.

In another example implementation, a method may include: 1) coupling a cooler plate with a frame structure that includes an inlet and an outlet, and 2) coupling a manifold plate with the frame structure. The cooler plate may include a module side and a heatsink side, the module side being configured to host a plurality of electronic modules disposed along a longitudinal axis extending between the inlet and the outlet, and the heatsink side including an array of protrusions configured to transfer heat from the plurality of electronic modules to fluid flowing through the array of protrusions. The manifold plate may include a cooling side and a distribution side connected via a venting system that allows fluid communication through the manifold plate, the cooling side being coupled to the array of protrusions and the distribution side being configured to direct fluid entering the inlet to flow through the array of protrusions in a transverse direction that is substantially perpendicular to the longitudinal axis before being exiting the outlet.

In a general aspect of this example implementation, the method may further comprise coupling the plurality of electronic modules to the module side of the cooler plate.

Each of the preceding example implementations and the various aspects described therewith will be understood to be illustrative of the types of implementations that are consistent with the following description. It will be understood that these examples are not intended to be limiting and that any of the aspects mentioned above or described herein may be used with any of the implementations in accordance with principles described herein.

The details of these and other implementations are set forth in the accompanying drawings and the description below. Other features will also be apparent from the following description, drawings, and claims.

### BRIEF DESCRIPTION OF THE DRAWINGS

FIG. 1 shows an illustrative cooler assembly for actively cooling a plurality of electronic modules in accordance with principles described herein.

FIG. 2A shows certain illustrative aspects of an implementation of the cooler assembly of FIG. 1 in accordance with principles described herein.

FIG. 2B shows additional illustrative aspects of an implementation of the cooler assembly of FIG. 1 in accordance with principles described herein.

FIG. 2C shows illustrative aspects of how an implementation of the cooler assembly of FIG. 1 may function as a drop-in replacement for a legacy cooler assembly in accordance with principles described herein.

FIG. 3A shows illustrative aspects of an implementation of a manifold plate for a cooler assembly in accordance with principles described herein.

FIG. 3B shows additional illustrative aspects of an implementation of a manifold plate for a cooler assembly in accordance with principles described herein.

FIG. 3C shows additional illustrative aspects of an implementation of a manifold plate for a cooler assembly in accordance with principles described herein.

FIG. 3D shows additional illustrative aspects of an implementation of a manifold plate for a cooler assembly in accordance with principles described herein.

FIG. 4A shows illustrative aspects of an implementation of a cooler plate for a cooler assembly in accordance with principles described herein.

FIG. 4B shows additional illustrative aspects of an implementation of a cooler plate for a cooler assembly in accordance with principles described herein.

FIG. 4C shows additional illustrative aspects of an implementation of a cooler plate for a cooler assembly in accordance with principles described herein.

FIG. 4D shows additional illustrative aspects of an implementation of a cooler plate for a cooler assembly in accordance with principles described herein.

FIG. 4E shows additional illustrative aspects of an implementation of a cooler plate for a cooler assembly in accordance with principles described herein.

FIG. 5 shows an illustrative method for constructing a cooler assembly for electronic modules in accordance with principles described herein.

### DETAILED DESCRIPTION

Cooler assemblies configured for active cooling of electronic modules are described herein. For example, a cooler assembly may be used to actively cool electronic modules in scenarios where passive cooling may be insufficient. As one example use case for such a cooler assembly, a drivetrain for an electric vehicle will be considered. The drivetrain may use several power modules associated with different stages of a direct-current (DC) to alternating-current (AC) conversion circuit. Because such power modules would consume and produce significant power (and often within relatively enclosed spaces), these devices may require active cooling to pump heat away and maintain the modules at suitable operating temperatures. Other example use cases, including use cases described herein, may similarly benefit from the same principles.

A cooler assembly may be configured to host a plurality of electronic modules. For example, the power modules mentioned above could be disposed in a row (i.e., collinearly) along a longitudinal axis of a cooler that includes a heat sink and that allows fluid (e.g., a suitable liquid coolant or other suitable cooling fluid) to move over the heat sink to thereby absorb and carry away heat generated by the electronic modules.

One technical challenge presented by conventional cooler assemblies of this type arises as the fluid is directed to move along the longitudinal axis to thereby absorb heat from each of the electronic modules in series. For example, if the electronic modules are disposed on the cooler assembly with a first electronic module on the left, a second electronic module in the middle, and a third electronic module on the right, fluid moving under the electronic modules from left to right would absorb heat first from the first electronic module, then from the second electronic module, and finally from the third electronic module. If a sufficient volume of fluid is pumped through the cooler assembly, it may be possible to transfer enough heat to ensure that each of the three modules of this example is sufficiently cooled to meet desired parameters. However, as a result of the serial heat transfer and the order of the modules with respect to the flow of the fluid, the first module will always be cooled to a greater degree by cooler fluid than the second and third electronic modules, which are cooled by fluid that has already absorbed energy from upstream modules. Consequently, even if certain temperature value targets can be achieved (e.g., maintaining measured temperature values for each module below a certain threshold), it may be difficult or impossible with this type of setup to meet temperature uniformity targets (e.g., ensuring that measured temperature values for each module are within a threshold of one another).

The effect of this challenge, if not addressed, is that the different electronic modules may be operated at different temperatures that cause the electronic modules to perform differently, possibly in undesirable ways. For example, in the process of bringing the temperature of the third electronic module to 10 degrees below a particular threshold, a conventional cooler assembly may bring the temperature of the second module to 20 degrees below the threshold and may bring the temperature of the third module to 30 degrees below the threshold. While all of the modules may therefore be operating below the threshold and within their operating parameters, the first module would be running 20 degrees cooler than the third module, which may affect the performance of the two modules in ways that are difficult to predict and compensate for and/or that are otherwise undesirable.

Another technical challenge associated with a conventional cooling assembly that passes fluid over the electronic modules in a serial manner such as described above relates to the pressure needed to pump the fluid through the cooling assembly. Because the fluid has to pass all the way through the cooler assembly under pressure, the energy used by the pump may be significant and may not be used efficiently. For example, some of the energy consumed by the fluid pumping serves to cool the first electronic module more than may be necessary or desirable for the first electronic module standing alone (i.e., if the first electronic module were not in series with the second and third electronic modules in this example). This inefficiency could be wasteful and could result in undesirable consequences such as shorter battery life for the system (e.g., an electric vehicle in the drivetrain example) and/or more severe pumping requirements (e.g., requiring pumps that take up more space, consume more power to operate, are heavier, etc.).

Cooler assemblies described herein provide technical solutions to the technical problems described above. Specifically, cooler assemblies described herein may maintain a same form factor as certain legacy cooler assemblies (e.g., in some cases serving as drop-in replacements for legacy cooler assemblies) while introducing internal manifolds and heatsinks described herein that direct cooling fluid to flow through the heatsinks in a substantially transverse direction (i.e., a direction substantially perpendicular to the longitudinal axis of the cooler assembly). In this way, each of the electronic modules along the longitudinal axis may be cooled in parallel, rather than in series, and a particular volume of fluid may largely absorb heat from only one of the electronic modules (rather than all of them). As a result, the heatsinks may be able to introduce more resistance to the fluid to thereby achieve greater cooling without increasing the overall pressure required of the pumps. For example, heatsinks configured for fluid moving in transverse directions (substantially perpendicular to the longitudinal axis of a cooler assembly) may have narrower protrusions (e.g., fins, pins, etc.) and narrower channels between the protrusions to thereby increase the surface area and cooling ability of the heatsinks. Additionally, multiple electronic modules being cooled in parallel may be cooled more uniformly and efficiently, with each being cooled to about the desired temperature (rather than a first electronic module in the series being overcooled in order that a later electronic module in the series may achieve a certain target).

Technical effects of technical solutions provided by cooler assemblies described herein may therefore include benefits such as more efficient and uniform cooling of electronic modules, more efficient pumping of cooling fluid (which may be performed by smaller and more streamlined pumps), convenient transition from legacy coolers to improved coolers (satisfying the same parameters and using the same form factor so as to serve as a drop-in replacement), customizable flow guide designs (e.g., with different protrusion shapes and flow distribution profiles as will be described in more detail below), and so forth.

Various implementations will now be described in more detail with reference to the figures. It will be understood that the particular implementations described below are provided as non-limiting examples and may be applied in various situations. Additionally, it will be understood that other implementations not explicitly described herein may also fall within the scope of the claims set forth below. Cooler assemblies for electronic modules in accordance with principles described herein may result in any or all of the technical benefits mentioned above, as well as various additional technical benefits that will be described and/or made apparent below.

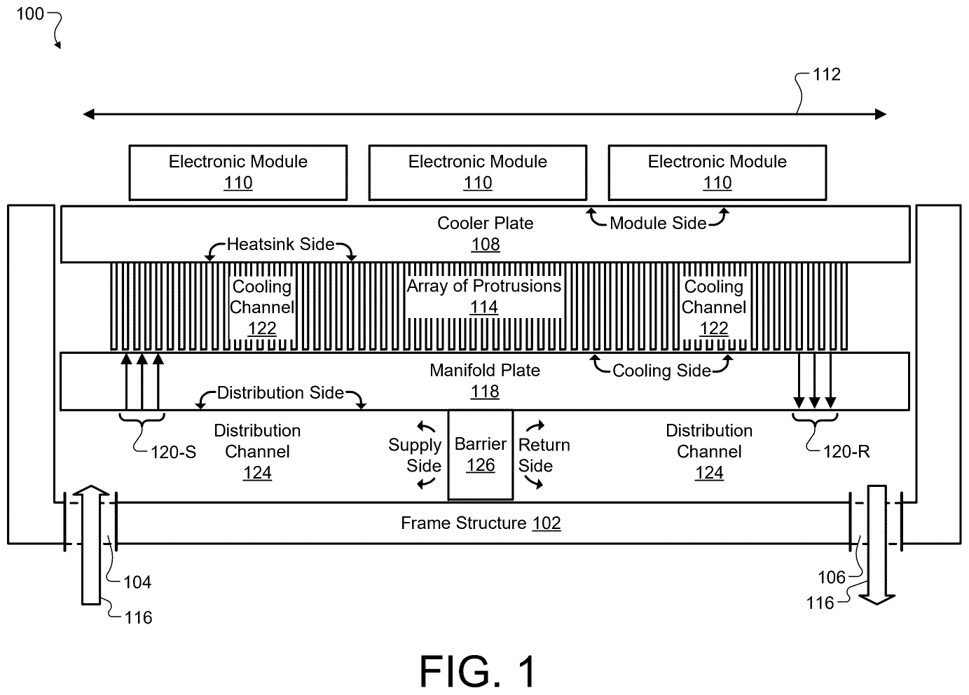

FIG. 1 shows an illustrative cooler assembly 100 for actively cooling a plurality of electronic modules in accordance with principles described herein. A generalized implementation of cooler assembly 100 is shown in a cross-sectional side view in FIG. 1. While various elements of cooler assembly 100 are illustrated and described in relation to FIG. 1, additional details and other optional elements, which will be understood to apply to this implementation and/or to other implementations of cooler assembly 100, will be illustrated and described in relation to other figures below.

In FIG. 1, cooler assembly 100 is shown to include a frame structure 102 (also referred to as an enclosure, a chassis, a jacket, etc.) that includes an inlet 104 and an outlet 106. A cooler plate 108 is shown to be coupled to frame structure 102. As shown, cooler plate 108 may include a module side (the top side of the plate as it is oriented in FIG. 1) and a heatsink side (the bottom side of the plate as it is oriented in FIG. 1). FIG. 1 shows that the module side (labeled “Module Side”) may be configured to host a plurality of electronic modules 110 (three distinct electronic modules 110 in this example) that may be disposed along a longitudinal axis 112 that extends between inlet 104 and outlet 106. The heatsink side (labeled “Heatsink Side”) of cooler plate 108 may then include an array of protrusions 114 (e.g., an array of fins, pins, or other suitable protruding structures described herein) configured to transfer heat from the plurality of electronic modules 110 to fluid 116 that flows through array of protrusions 114 in accordance with principles that will be described. Specifically, for example, fluid 116 may enter cooler assembly 100 at inlet 104 (as shown), may be directed to flow in a transverse direction through the array of protrusions 114 to thereby draw heat away from electronic modules 110, and may eventually exit at outlet 106.

The directing of fluid 116 to flow through the array of protrusions 114 in this transverse direction (rather than flowing through the protrusions, for example, in a direction substantially parallel to longitudinal axis 112) may be facilitated by a manifold plate 118 that, as shown, may also be coupled to frame structure 102. Manifold plate 118 may include a cooling side (the top side of the plate as it is oriented in FIG. 1) and a distribution side (the bottom side of the plate as it is oriented in FIG. 1) that may be connected via a venting system that allows fluid communication (of fluid 116) through manifold plate 118. Specifically, as illustrated by arrows through manifold plate 118 in FIG. 1, the venting system may include a supply vent network 120-S (‘S’ for “Supply”), through which fluid 116 passes through manifold plate 118 in a first direction, and a return vent network 120-R (‘R’ for “Return”), through which fluid 116 passes back through manifold plate 118 in the opposite direction.

As illustrated in FIG. 1, the cooling side (labeled “Cooling Side”) of manifold plate 118 may be coupled (e.g., immediately adjacent to, touching or very nearly touching) to the array of protrusions 114 so as to disallow much (if not all) fluid 116 from passing between protrusions 114 and manifold plate 118 (instead directing or forcing the fluid to pass between the protrusions). The distribution side (labeled “Distribution Side”) of manifold plate 118 may then be configured to direct fluid 116 entering inlet 104 to flow through the array of protrusions 114 in the transverse direction that is substantially perpendicular to longitudinal axis 112 (e.g., into or out of the page from the side view perspective of FIG. 1) before exiting outlet 106. Details regarding how manifold plate 118 accomplishes this flow control will be described in more detail below.

The preceding description of cooler assembly 100 has referred to various structural elements (e.g., frame structure 102, cooler plate 108, manifold plate 118, etc.) that may be assembled to form the cooler assembly. FIG. 1 also labels certain functional elements (e.g., channels between the plates, etc.) that result from these structural elements. Specifically, as shown, cooler assembly 100 may include, along with inlet 104 and outlet 106 through frame structure 102, a cooling channel 122 that includes the array of protrusions 114 configured to transfer heat from the plurality of electronic modules 110 to fluid 116 flowing through the array of protrusions 114 (the plurality of electronic modules 110 again being disposed along the longitudinal axis 112 extending between inlet 104 and outlet 106). Cooler assembly 100 may further include a distribution channel 124 that is in fluid communication with cooling channel 122 via the venting system (e.g., the supply vent network 120-S and the return vent network 120-R). Distribution channel 124 may be configured to direct fluid 116 entering at inlet 104 to flow through cooling channel 122 in the transverse direction substantially perpendicular to longitudinal axis 112 (e.g., into and/or out of the page from the perspective of FIG. 1) before exiting at outlet 106.

The general implementation of cooler assembly 100 in FIG. 1 shows that distribution channel 124 may include a barrier 126 between a supply side of the distribution channel that includes inlet 104 (labeled “Supply Side”) and a return side of the distribution that includes outlet 106 (labeled “Return Side”). As shown and mentioned above, the venting system may include supply vent network 120-S on the supply side of barrier 126, and may include return vent network 120-R on the return side of barrier 126. While not depicted with particularity in this view, it will be understood (and depicted in detail in various views illustrated below) that barrier 126 may be formed so as to direct fluid 116 to flow through cooling channel 122 in the transverse direction. To this end, barrier 126, supply vent network 120-S, and return vent network 120-R may each extend a distance along longitudinal axis 112 that spans the plurality of electronic modules 110 (not shown in FIG. 1, but shown in other figures below). As such, barrier 126 may be configured to direct fluid 116 entering inlet 104 to flow to outlet 106 via supply vent network 120-S, cooling channel 122, and return vent network 120-R.

Referring to these elements more structurally, FIG. 1 shows that the distribution side of manifold plate 118 may include the barrier 126 between the supply side that includes inlet 104 and the return side that includes outlet 106. The venting system through manifold plate 118 may then include, as has been described, the supply vent network 120-S on the supply side of barrier 126 and the return vent network 120-R on the return side of barrier 126, where both the supply vent network 120-S and the return vent network 120-R extend a distance along longitudinal axis 112 that spans the plurality of electronic modules 110 (again, not shown in FIG. 1 but illustrated in more detail below). Barrier 126 may be configured to direct fluid 116 entering inlet 104 to flow to outlet 106 by passing through manifold plate 118 (e.g., via supply vent network 120-S), passing through the array of protrusions 114, and returning through manifold plate 118 (e.g., via return vent network 120-R).

A cooler assembly such as cooler assembly 100 may be used to actively cool any suitable type or types of electronic modules 110 as may serve a particular implementation. As has been mentioned, one example of an application or use case for such a cooler assembly could be an automotive use case, such as for a drive train of an electric vehicle. Electric vehicles typically include electric batteries that supply direct-current (DC) power that must be converted (typically in several phases) to alternating-current (AC) power that is suitable for the vehicle's engine. Accordingly, in one example use case, the plurality of electronic modules 110 shown in FIG. 1 could include power electronics for a plurality of phases of a DC-to-AC conversion circuit configured for use in an electric vehicle drivetrain. For instance, each electronic module 110 may be a similar or identical module, such that it would be desirable (for efficiency and performance) that each electronic module 110 operates at approximately the same temperature.

In other examples, it will be understood that the electronic modules 110 could be implemented by other types of power electronics for other types of use cases (besides electric vehicles). Indeed, in certain implementations, the electronic modules may be other types of electronics that call for active cooling, such as processors (e.g., CPUs, GPUs, etc.) that generate significant heat in a high-powered server computer or the like. In either of these illustrative use cases, as well as in various other possible applications, the electronic modules may be identical, similar, or completely different from one another in terms of how much cooling is needed. For instance, while examples of similar components with similar needs have been described above (and are assumed for most of the specific examples described herein), it will be understood that one electronic module 110 may be a first type of module that tends to consume significant power and require significant cooling, while another electronic module 110 may be a second type of module that consumes significantly less power and therefore requires less cooling. As will be described in more detail below, implementations of cooler assembly 100 may be customized in various ways to handle a variety of situations with different electronic modules in need of different amounts of cooling.

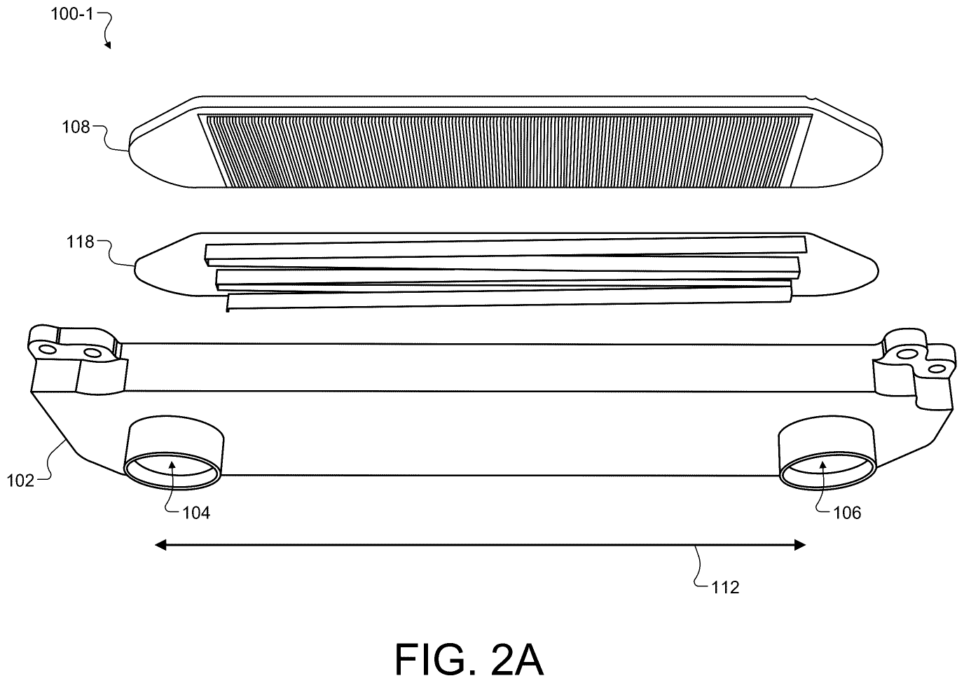

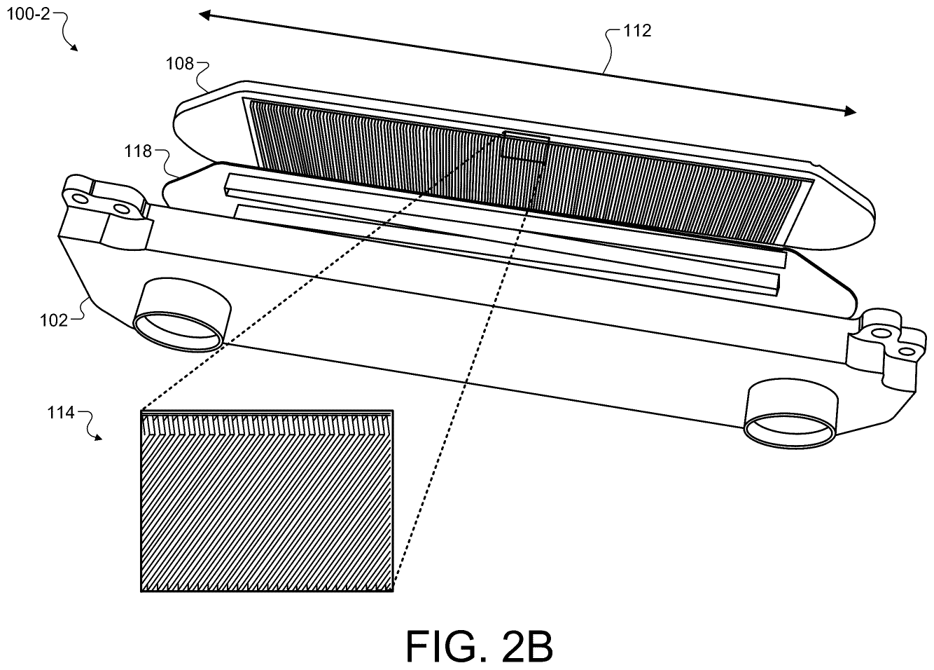

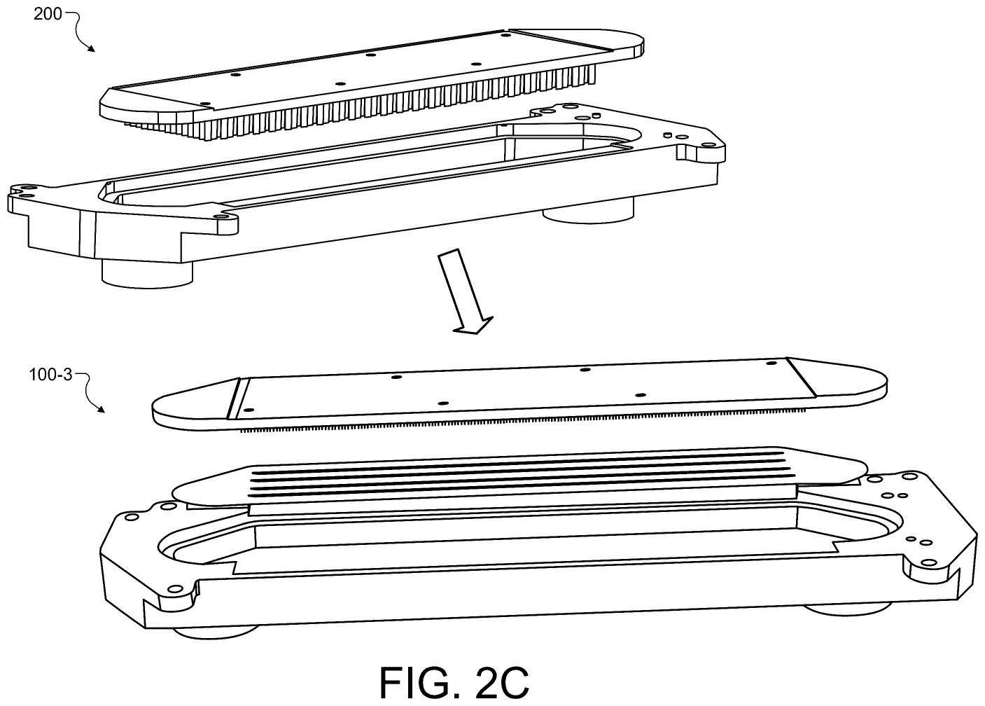

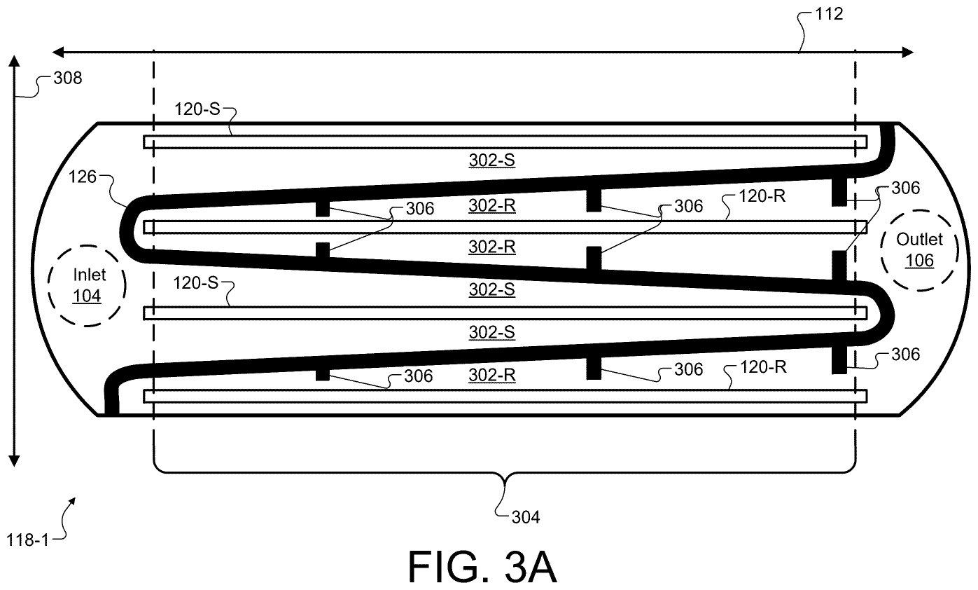

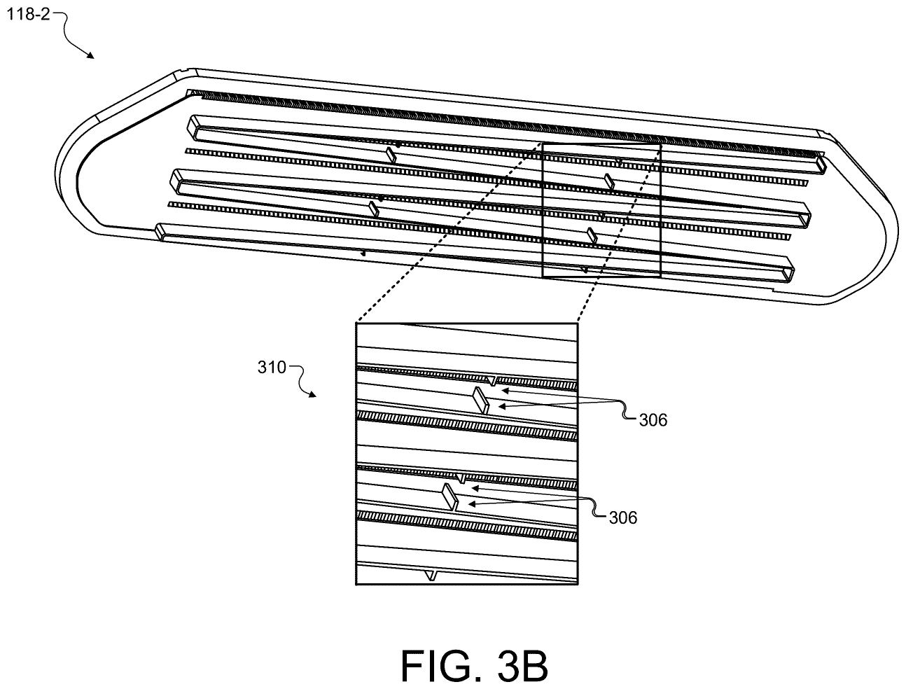

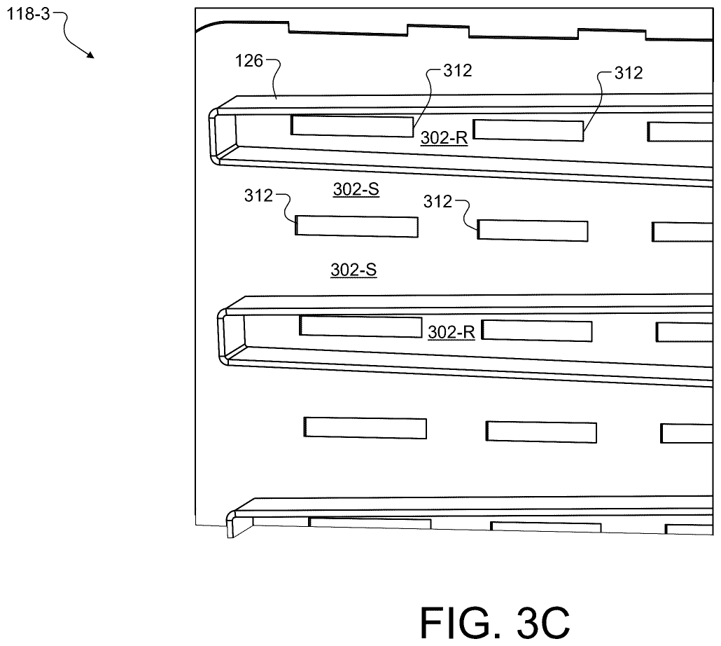

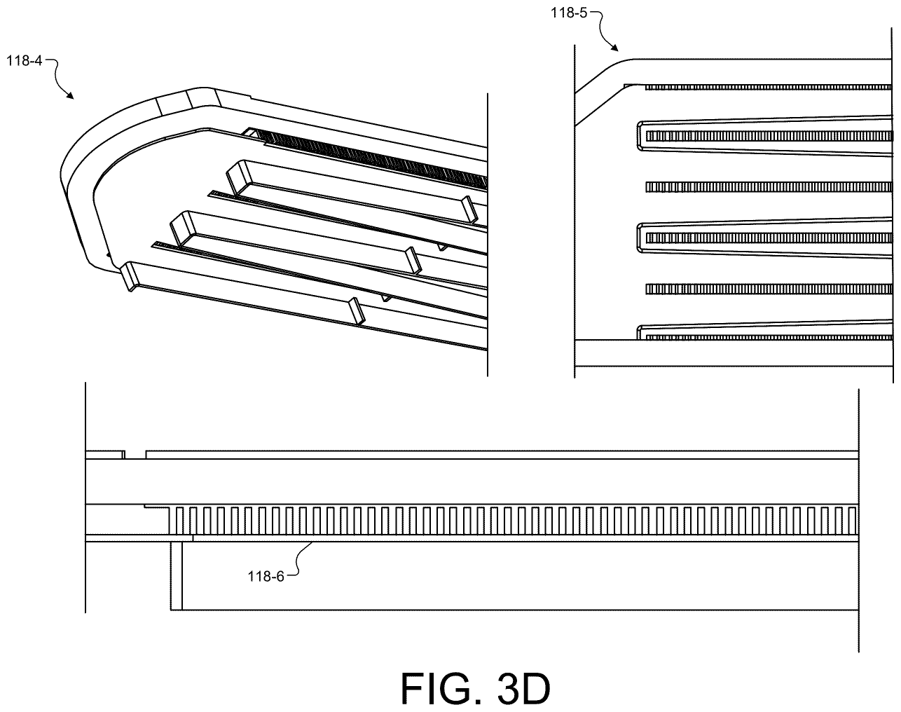

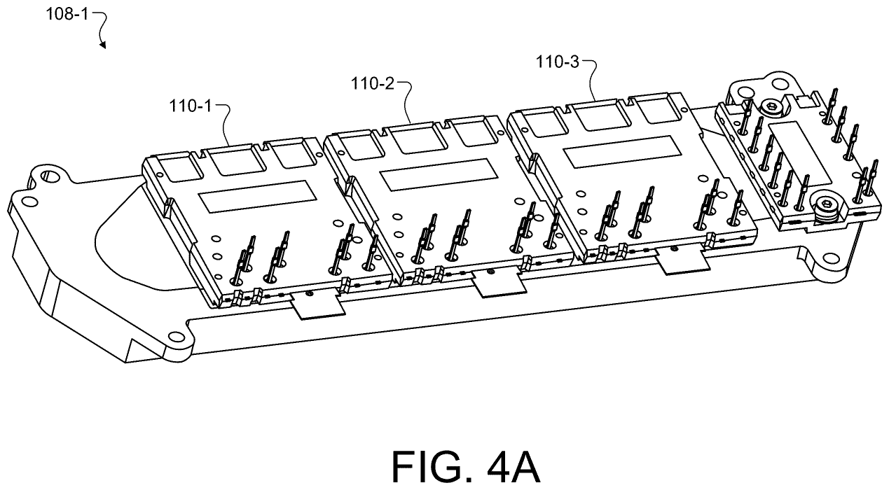

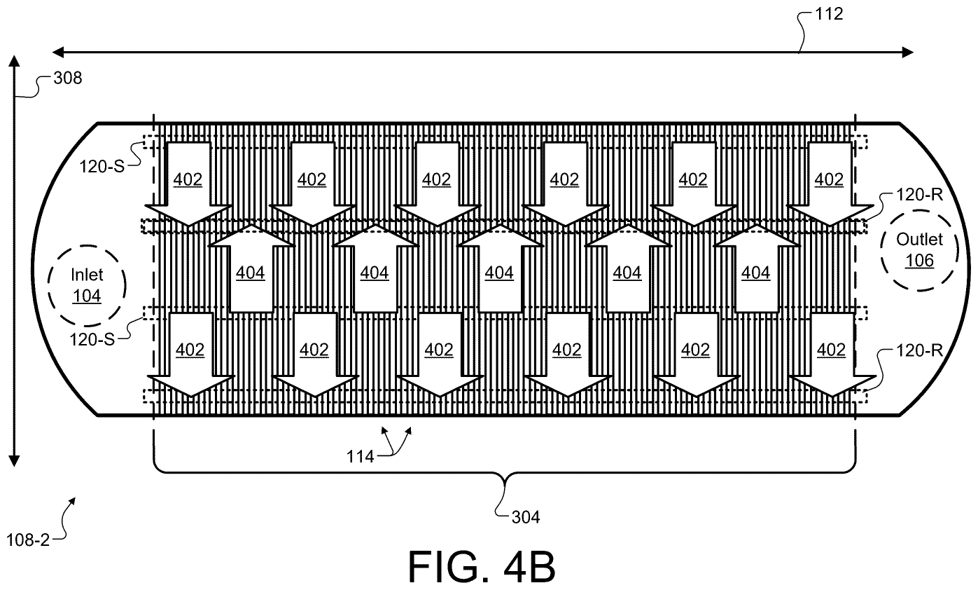

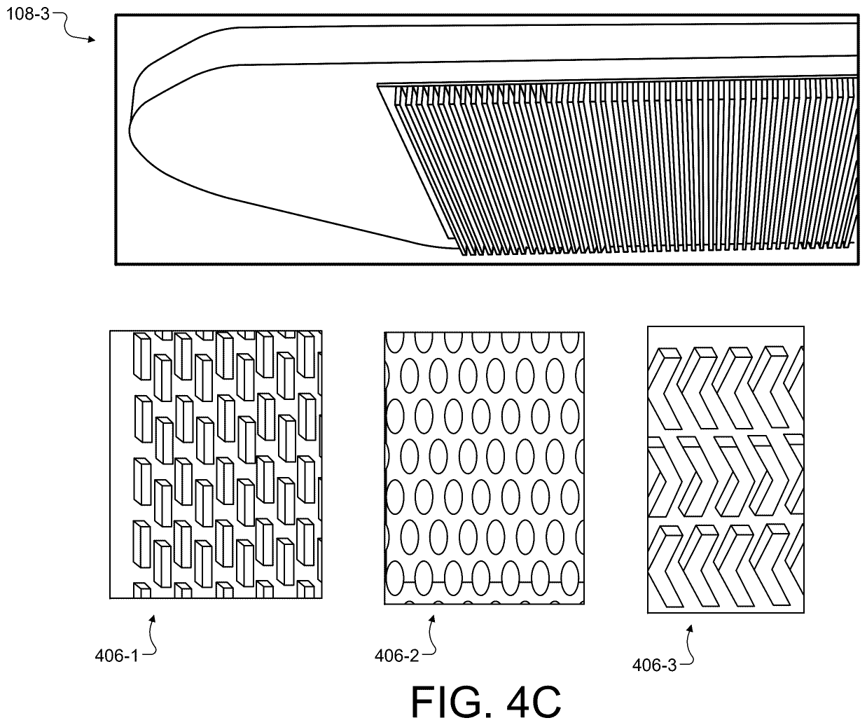

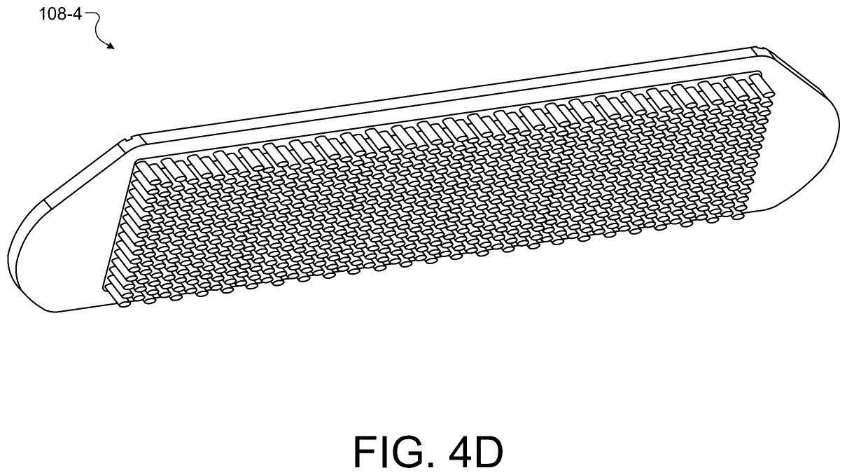

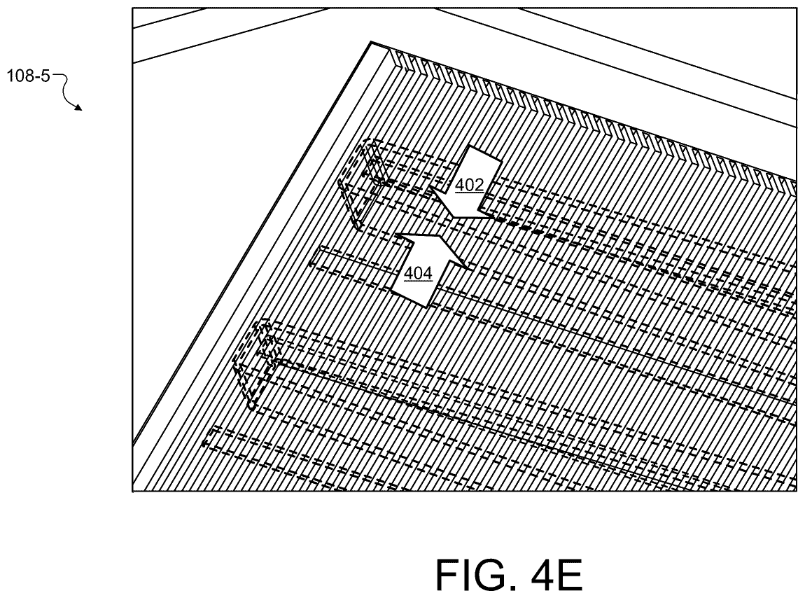

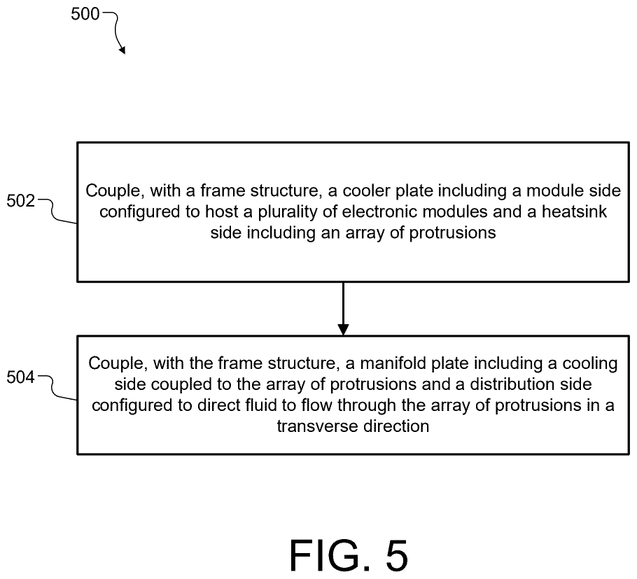

As mentioned above, FIG. 1 illustrates a generalized implementation of cooler assembly 100 to show certain elements that may be present in various cooler assembly implementations in accordance with principles described herein. Additional details about some of these elements, as well as additional elements that may be present in certain implementations, will now be described. Specifically, FIGS. 2A-2C show more detailed images (with different types of views, from a variety of angles, etc.) to illustrate certain principles associated with the cooler assemblies in their entirety (as assembled). Thereafter, various figures will be described to explore specific elements of cooler assembly 100 in more detail. For example, FIGS. 3A-3D show various details associated with implementations of manifold plate 118 to illustrate principles relating to distribution channel 124, while FIGS. 4A-4E shows various details associated with implementations of cooler plate 108 to illustrate principles relating to electronic modules placement and to cooling channel 122. FIG. 5 then illustrates an example method for constructing an implementation of cooler assembly 100.

FIG. 2A shows certain illustrative aspects of an implementation of cooler assembly 100 in accordance with principles described herein. More particularly, FIG. 2A shows an implementation 100-1 of cooler assembly 100 in an exploded view from an angled perspective to gives a better conception of how cooler assembly 100 may be implemented in three dimensions when fully assembled. As shown, implementation 100-1 includes the frame structure 102 with a large round inlet 104 where fluid may enter (as pushed in by a pump, not explicitly shown) and a large round outlet 106 where fluid may exit (e.g., to return to the pump). Similarly as shown in FIG. 1, a longitudinal axis 112 may be associated with implementation 100-1, such that inlet 104 is on one end of the cooler assembly and outlet 106 is on the other end with respect to the longitudinal axis 112.

Implementations of manifold plate 118 and cooler plate 108 are also shown in the exploded view of implementation 100-1 in FIG. 2A. As shown, manifold plate 118 may be coupled (e.g., integrated) with frame structure 102 near the bottom of the cooler adjacent to inlet 104 and outlet 106. Above manifold plate 118, cooler plate 108 may be coupled. The module side of cooler plate 108 is shown in FIG. 2A to be cleared and ready to host a plurality of electronic modules 110 (which are not explicitly shown in FIG. 2A). While not explicitly shown in FIG. 2A, it will be understood that fluid 116 entering at inlet 104 may be directed by a barrier on the distribution side of manifold plate 118 to flow upward through a venting system within manifold plate 118 toward cooler plate 108. From there, the fluid may flow in a substantially transverse direction through protrusions on the heatsink (bottom) side of cooler plate 108 (not visible in this view) to draw heat away from electronic modules 110 that would be installed on the module (top) side of cooler plate 108. The fluid may then flow back down through the venting system, passing through manifold plate 118 and exiting through outlet 106.

FIG. 2B shows an implementation 100-2 of cooler assembly 100 in a similar type of exploded view as shown in FIG. 2A. Implementation 100-2 includes the same elements described above in relation to implementation 100-1 (e.g., frame structure 102, manifold plate 118, and cooler plate 108, etc.) but flips cooler plate 108 so that the heatsink side (rather than the manifold side) is visible. As shown, the heatsink side of cooler plate 108 includes the array of protrusions 114, a portion of which is shown in a closeup view in FIG. 2B. As shown, protrusions 114 may create narrow microchannels for the fluid to flow through in a transverse direction substantially perpendicular to longitudinal axis 112. Such microchannels may be constructed, for example, by extrusion or skiving. As such, fluid may be directed to flow through the channels in this transverse direction, rather than in a longitudinal direction that would be substantially parallel to longitudinal axis 112. Since the plurality of electronic modules 110 are disposed along the longitudinal axis 112, this movement of fluid causes each electronic module 110 to essentially be cooled in parallel with the others by a dedicated volume of fluid. In other words, fluid that draws heat away from one electronic module 110 may be directed to flow directly from that electronic module to outlet 106 (to be cooled and recirculated by the pumps), rather than passing serially under each of the various electronic modules 110 before exiting outlet 106.

FIG. 2C shows illustrative aspects of how an implementation of the cooler assembly of FIG. 1 may function as a drop-in replacement for a legacy cooler assembly in accordance with principles described herein. More particularly, FIG. 2C shows a legacy cooler assembly 200 that includes a similar frame structure and cooler plate that is configured to host electronic modules on a module side and that includes an array of protrusions (albeit not as fine or narrow as shown in FIG. 2B) on a heatsink side that goes into the frame structure. For the legacy cooler assembly 200, there is no manifold plate 118 directing the fluid to flow in the transverse manner, nor do the protrusions (implemented as individual pin protrusions in this case, rather than fin-shaped protrusions forming microchannels such as shown in FIG. 2B) serve to disallow fluid to flow in the longitudinal direction. As a result, fluid entering at the inlet of legacy cooler assembly 200 may be expected to pass through the protrusions in the longitudinal direction, thereby cooling the plurality of modules (not shown in FIG. 2C) in a serial fashion and somewhat nonuniform manner (since the fluid gets warmer and warmer as it absorbs heat from each successive electronic module in the series).

In contrast to the legacy cooler assembly 200, FIG. 2C also shows an implementation 100-3 of cooler assembly 100, which, as with other examples above, is shown to include both the cooler plate 108 and the manifold plate 118. Accordingly, fluid entering the inlet of this cooler assembly 100 may be directed to flow in the transverse direction to thereby cool the electronic modules in a parallel manner that allows them to be cooled more uniformly and with less fluid pressure and/or more aggressive cooling associated with the narrower microchannels (described above) between the protrusions in the array.

One advantage that has been mentioned for cooler assemblies according to principles described herein is that the cooler assemblies may match legacy coolers in both operating parameters and form factors so as to serve as drop-in replacements for such legacy coolers. This benefit is illustrated in FIG. 2C, where both legacy cooler assembly 200 and implementation 100-3 will be understood to include a same form factor when fully assembled with their respective components. It will also be understood that the operating parameters of the two may be compatible, such as by implementation 100-3 offering matching or improved performance for each relevant parameter. More particularly, implementation 100-3 of cooler assembly 100 may be associated with a first pressure parameter and a first temperature parameter that respectively meet or improve upon a second pressure parameter and a second temperature parameter of legacy cooler assembly 200. Additionally, implementation 100-3 of cooler assembly 100 may be associated with a form factor equivalent to legacy cooler assembly 200 so as to function as a drop-in replacement for legacy cooler assembly 200.

As with other detailed features described herein, it will be understood that the principles described in relation to FIG. 2C are optional and may not apply to all implementations of cooler assembly 100. For example, other implementations of cooler assembly 100 may have different operating parameters than legacy cooler assembly 200 and/or may have different form factors (e.g., so help increase the performance even more over legacy components), such that they would not necessarily serve as drop-in replacements for legacy components and may call for additional design work to fully integrate.

FIG. 3A shows illustrative aspects of an implementation 118-1 of manifold plate 118 for cooler assembly 100 in accordance with principles described herein. Specifically, in contrast to the illustration of manifold plate 118 in FIG. 1, FIG. 3A shows implementation 118-1 of manifold plate 118 from a bottom view to better illustrate how barrier 126 may be implemented (on the distribution side) to help direct the entering fluid 116 in the ways described herein.

As shown, implementation 118-1 of the manifold plate may form (when the distribution side of the plate is coupled to an implementation of frame structure 102) a distribution channel (i.e., distribution channel 124) that includes the barrier 126 between a supply side 302-S (‘S’ for “Supply”) that includes inlet 104, and a return side 302-R (‘R’ for “Return”) that includes outlet 106. While inlet 104 and outlet 106 may be implemented in frame structure 102 and not in manifold plate 118 (as illustrated elsewhere), dotted lines on implementation 118-1 show where the fluid ports are located with respect to the manifold plate since the ports do open into the distribution channel and are separated by barrier 126. Moreover, as shown, barrier 126 not only separates inlet 104 from outlet 106 but also divides the venting system into the supply vent network 120-S and the return vent network 120-R. Specifically, as shown in FIG. 3A, the venting system includes a supply vent network 120-S on supply side 302-S of barrier 126 that includes several long supply vents (slits or openings in the manifold plate 118) that allow fluid 116 entering at inlet 104 to pass through the manifold plate 118 into the cooling channel 122 (not shown in FIG. 3A). Moreover, as further shown in FIG. 3A, the venting system includes a return vent network 120-R on return side 302-R of barrier 126 that includes several long return vents that allow fluid 116 to pass through from cooling channel 122 and to exit outlet 106.

While the cross-sectional side view of FIG. 1 did not lend itself to illustrating it, FIG. 3A shows how the vents of the venting system (i.e., the vents of supply vent network 120-S and return vent network 120-R), as well as the barrier 126 itself, may extend longitudinally along the length of the cooler assembly 100. More particularly, as shown, supply vent network 120-S and return vent network 120-R are each shown to extend a distance along longitudinal axis 112 that spans the plurality of electronic modules. For example, while the electronic modules 110 are not shown in FIG. 3A, it will be understood that a span 304 illustrated by a bracket and dashed lines along longitudinal axis 112 represents the location covered by the plurality of electronic modules 110 on another layer of the cooler (i.e., on the module side of cooler plate 108 as illustrated elsewhere).

Each of the vents is shown to cover at least this full span 304 and barrier 126 is shown to zigzag longitudinally so as to separate the supply vent network 120-S on the supply side 302-S from the return vent network 120-R on the return side 302-R. Accordingly, as shown, the supply side 302-S and return side 302-R may not actually be divided in the middle or at any particular point along longitudinal axis 112. Rather, as emphasized by the labels for both sides 302-S and 302-R being aligned in the middle of implementation 118-1, both sides 302-S and 302-R span all of the electronic modules 110 so that fluid 116 can flow under the electronic modules in a substantially transverse direction along a transverse axis 308 shown to be perpendicular to longitudinal axis 112. For example, fluid 116 may be directed by barrier 126 to flow transversely (i.e., substantially parallel to transverse axis 308) through various vents in the supply vent network 120-S, through the cooling channel 122 (not shown in FIG. 3A) to various vents in the return vent network 120-R.

Accordingly, while fluid 116 may flow in the longitudinal direction in the distribution channel 124, these long venting networks and this longitudinally zigzagging barrier 126 may direct the fluid 116 to flow in the transverse direction through the cooling channel 122, which is where the fluid primarily absorbs heat from the electronic modules 110. In other words, as shown by the zigzag shape of barrier 126 in FIG. 3A, barrier 126 may be configured to direct fluid entering inlet 104 to flow to outlet 106 via supply vent network 120-S, cooling channel 122 (understood to be behind this manifold plate 118 but not explicitly shown in FIG. 3A), and return vent network 120-R.

In this example, a plurality of vents from supply vent network 120-S and from return vent network 120-R are shown to be interleaved (i.e., in a pattern that alternates between supply vents and return vents) such that the barrier 126 separating supply side 302-S and return side 302-R extends back and forth along the longitudinal axis in the zigzag pattern that has been described. It will be understood that other implementations may include more or fewer and differently shaped barriers that still largely or entirely cover span 304 on the longitudinal axis 112. For instance, in one example, a single long supply vent could be above a barrier running the length of span 304 in a diagonal direction to separate the supply vent from a single long return vent. In another example, even more interleaved vents (more than the two supply vents of the supply vent network 120-S shown in FIG. 3A and more than the two return vents of the return vent network 120-R shown in FIG. 3A) could be included with a barrier that zigzags back and forth over span 304 more times than is shown in this example. In still another example, a single supply vent could feed two return vents or two supply vents could feed a single return vent with corresponding barriers that direct the fluid accordingly. In other words, the number of supply vents and the number of return vents could be different in certain implementations, as could the length of the vents, width of the vents, or other characteristics of the vents.

Another illustrative aspect illustrated in FIG. 3A, along with the barrier 126 between supply side 302-S and return side 302-R, is that the distribution channel may include a set of flow control features 306 that are each configured to resist or impede the flow of fluid. For example, as shown, flow control features 306 may include structures attached to barrier 126 (e.g., on return side 302-R of barrier 126 in this example) that are each configured to resist flow of fluid 116. Vertical groups of flow control features 306 are shown to be disposed, in this example, at locations along barrier 126 that would correspond, at least approximately, with each of the three electronic modules 110. By resisting (but still allowing) the flow of fluid 116 at these locations, flow control features 306 may help direct and manage the pressure and flow of fluid 116 in desirable ways in accordance with the cooling objectives of a given implementation. For example, strategic placement and sizing of flow control features such as the flow control features 306 illustrated in FIG. 3A may help direct an approximately equal volume of fluid 116 to pass through protrusions 114 beneath each electronic module 110 or, if desired, could help direct differing amounts of fluid to different modules in accordance with the cooling objectives of specific electronic modules cooled by a particular implementation.

In a first specific example, the electronic modules 110 to be cooled may be identical or nearly identical (e.g., equivalent) modules in certain implementations, such that an identical or similar rate of fluid flow is desired. For instance, the plurality of electronic modules 110 may include a first electronic module and a second electronic module each warranting a same amount of cooling. In these types of examples, the set of flow control features 306 may be arranged to direct fluid to flow at an equivalent flow rate for the first electronic module and for the second electronic module. Alternatively, the plurality of electronic modules 110 to be cooled in a second specific example may be different in various ways, such that different amounts of cooling are called for. For instance, the plurality of electronic modules 110 may include a first electronic module and a second electronic module where the second electronic module warrants a different amount of cooling as the first electronic module. In these types of examples, the set of flow control features 306 may be arranged to direct fluid to flow at different flow rates for the first electronic module and for the second electronic module. For example, flow control features 306 may be customized to direct significantly more fluid to flow under the first electronic module than under the second electronic module if that were desired for a particular use case or set of electronic modules.

FIG. 3B shows an implementation 118-2 of manifold plate 118 from an angled perspective (i.e., a perspective that is neither straight-on from the bottom, as with the view of FIG. 3A, or straight-on from the side, as with the view of FIG. 1). Implementation 118-2 includes the same elements described above in relation to implementation 100-1, including, for example, interleaved networks of supply and return vents, a barrier that zigzags between the vents, certain flow control features 306 on the return side of the barrier, and so forth. A closeup view 310 of a portion of implementation 118-2 is shown to better illustrate how flow control features 306 may integrate with the barrier on the return side of the barrier. Additionally, while the vents may be implemented by long openings in implementation 118-2, a large number of fine lines perpendicular to the openings are shown to be drawn in each vent to represent the array of protrusions that would be present directly on the other side of the manifold plate 118 (i.e., on the cooling side of manifold plate 118 due to the array of protrusions 114 on the heatsink side of the cooler plate 108). As such, incoming fluid that passes up through any of the supply vents will immediately be forced, by the protrusions 114, to flow in a transverse direction through the protrusions until reaching a return vent. Only then will the fluid be free to flow back down through the manifold plate 118 to the distribution channel, where it will then be free (though possibly somewhat impeded by flow control features 306) to flow longitudinally toward outlet 106 where the fluid may exit the cooler assembly.

FIG. 3C shows, in close-up, a portion of an implementation 118-3 of manifold plate 118. While other examples have included vents implemented as long slits spanning most of the longitudinal axis 112 of the manifold plate (e.g., extending at least span 304 along the axis), implementation 118-3 shows an example in which the venting system includes a plurality of discrete slots 312 disposed along longitudinal axis 112 and each aligned to the longitudinal axis. For context, FIG. 3C shows labels for barrier 126 as the barrier separates discrete slots 312 on the supply side 302-S from discrete slots 312 on the return side 302-R. Along with other features described herein (e.g., barrier 126, flow control features 306, etc.), careful design of venting systems with discrete slots such as illustrated in FIG. 3C may allow for significant customizability of how a cooler assembly implementation performs, how much one electronic module is cooled with respect to another, and so forth.

FIG. 3D shows additional portions of additional implementations 118-4, 118-5, and 118-6 of manifold plate 118 to illustrate other views and other aspects that may apply to certain implementations. For example, implementation 118-4 of manifold plate 118 shows an example where flow control features are included on the supply side of the barrier rather than on the return side of the barrier to help manage fluid flow in a slightly different way as may be desirable for certain implementations. Implementation 118-5 of manifold plate 118 shows, in close-up, how fine the microchannels between the array of protrusions 114 may be when pressurized fluid flows up through the venting system. Implementation 118-6 of manifold plate 118 shows a side view to illustrate how the manifold plate may be coupled with the protrusions (i.e., by directly touching) to largely or completely disallow fluid from passing between the manifold plate and the protrusions, forcing it instead to pass through channels between the protrusions (so as to draw heat from the protrusions). Implementation 118-6 also shows that the array of protrusions may be low profile to make room for the manifold plate 118 in the frame structure.

FIG. 4A shows illustrative aspects of an implementation 108-1 of cooler plate 108 from an angled perspective that shows the module side with three electronic modules 110-1, 110-2, and 110-3 installed on the plate. As shown, the view of implementation 108-1 is from an angled perspective that is neither straight-on from the top nor straight-on from the side. The various electronic modules 110-1, 110-2, and 110-3 are shown to be identical or very similar modules in this example, such that it may be desirable for each to receive an equivalent amount of parallel active cooling. As has been mentioned, it will be understood that other examples may include more or fewer electronic modules and electronic modules that are different and/or require differing amounts of active cooling for which the cooler assembly may be specifically customized.

FIG. 4B shows illustrative aspects of an implementation 108-2 of cooler plate 108 from a bottom view (i.e., looking at the heat sink side of the plate). As shown, dashed lines illustrate where inlet 104, outlet 106, and various vents of supply vent network 120-S and return vent network 120-R may be located with respect to the cooler plate when the full cooler assembly is assembled (though it will be understood that these components are included on other elements of the cooler assembly, as described and illustrated elsewhere). The array of protrusions 114 is shown to extend along transverse axis 308 so that fluid may flow in the opposite transverse directions shown by flow indicators 402 and 404.

By directing fluid 116 to the supply vent network 120-S, the distribution channel may be configured to direct fluid to simultaneously flow through the cooling channel in both the transverse direction (e.g., represented by flow indicators 402) and in an additional transverse direction (e.g., represented by flow indicators 404) that is substantially perpendicular to longitudinal axis 112 and substantially opposite the transverse direction. In other words, for a given microchannel between two protrusions 114, fluid 116 may flow in two opposite directions between the various supply vents (from supply vent network 120-S where the fluid enters cooling channel 122 from distribution channel 124) and the various return vents (from return vent network 120-R where the fluid exits cooling channel 122 to return to distribution channel 124). In this example, the fin-shaped protrusions further help direct fluid 116 to flow only in the transverse directions (i.e., the transverse direction and the opposite transverse direction, both of which are substantially perpendicular to longitudinal axis 112). In particular, the array of protrusions 114 is shown to include, in this example, a series of planar fins disposed along the longitudinal axis and each aligned perpendicularly to longitudinal axis 112 to disallow flow of fluid along longitudinal axis 112 while allowing flow of fluid in the transverse directions (parallel to transverse axis 308).

Along these lines, FIG. 4C shows, in close-up, a portion of an implementation 108-3 of cooler plate 108 that likewise includes planar fins disposed along the longitudinal axis and aligned with the transverse axis. However, FIG. 4C further shows various alternative discrete protrusion styles that may be used together with or instead of the planar-style fin protrusions. For example, as shown, the array of protrusions may include an array of discrete protrusions 406-1, 406-2, 406-3, or other suitable discrete protrusions that do not extend the width of the cooler plate 108 along the transverse axis 308 as the illustrated planar fins do. By being discrete and leaving space along both the longitudinal and transverse axes, discrete protrusions such as shown in FIG. 4C may be configured to allow flow of fluid 116 both 1) along longitudinal axis 112 and 2) in the transverse directions (along transverse axis 308). For example, each discrete protrusion of the array of discrete protrusions 406-1 is shown to have a rectangular shape (e.g., straight protrusions), each discrete protrusion of the array of discrete protrusions 406-2 is shown to have a rounded shape (e.g., pin protrusions), and each discrete protrusion of the array of discrete protrusions 406-3 is shown to have a wavy shape (e.g., wave protrusions). These discrete arrays of protrusions are shown to be arranged in either a grid pattern or a staggered (i.e., misaligned) grid pattern such that fluid 116 may allowed, and somewhat encouraged, to flow in the transverse direction while also being allowed (if somewhat discouraged by the staggering of the discrete protrusion placement) to flow in the longitudinal direction.

FIG. 4D shows an implementation 108-4 of cooler plate 108 that includes discrete protrusions (i.e., pin protrusions with a rounded shape in this example). FIG. 4D shows implementation 108-4 of the cooler plate 108 from an angled perspective to show how the discrete protrusions may be implemented in three dimensions. It will be understood that other types of discrete protrusions may similarly be included on the heatsink side of an implementation of cooler plate 108 as may serve a particular implementation.

FIG. 4E shows an implementation 108-5 of cooler plate 108 that includes the planar fins and further illustrates, from an angled perspective, how fluid 116 may flow in opposite transverse directions in a given microchannel through the array of protrusions. Specifically, flow indicators 402 and 404 are shown to each be parallel with the direction forced by the planar fins but to be opposite one another. In this example, fluid from two different supply vents in shown to meet and exit cooling channel 122 at a same return vent. In FIG. 4E, the barrier is drawn for reference, though it will be understood that the barrier is implemented within the distribution channel 124 by manifold plate 118, rather than by implementation 108-5 of cooler plate 108.

FIG. 5 shows an illustrative method 500 for constructing a cooler assembly for electronic modules in accordance with principles described herein. For example, a cooler assembly such as cooler assembly 100 may be assembled or constructed based on the steps of FIG. 5. While FIG. 5 shows illustrative operations 502 and 504 according to one implementation, other implementations of method 500 may omit, add to, reorder, and/or modify any of the operations 502-504 shown in FIG. 5. In some examples, multiple operations shown in FIG. 5 or described in relation to FIG. 5 may be performed concurrently (e.g., in parallel) with one another, rather than being performed sequentially as illustrated and/or described. Each of operations 502 and 504 will now be described in more detail.

At operation 502, a cooler plate may be coupled with a frame structure. For example, as described and illustrated above with respect to implementations of frame structure 102, the frame structure used in this construction may include an inlet and an outlet whereby pressurized fluid (from a pump not necessarily included in the cooler assembly) may enter the cooler assembly (via the inlet) and exit the cooler assembly (via the outlet). Additionally, as has been described and illustrated with respect to various implementations of cooler plate 108, the cooler plate coupled to the frame structure for this assembly may include a module side and a heatsink side. The module side may be configured to host a plurality of electronic modules disposed along a longitudinal axis extending between the inlet and the outlet. Meanwhile the heatsink side may include an array of protrusions configured to transfer heat from the plurality of electronic modules to fluid flowing through the array of protrusions.

While not explicitly shown as part of method 500 (since the electronic modules may not be part of the cooler assembly being constructed, but, rather, may be installed later), it will be understood that an additional operation that could be included in method 500 involves coupling the plurality of electronic modules to the module side of the cooler plate.

At operation 504, a manifold plate may be coupled with the frame structure. For example, as described and illustrated above with respect to various implementations of manifold plate 118, the manifold plate coupled to the frame structure for this assembly may include a cooling side and a distribution side connected via a venting system that allows fluid communication through the manifold plate. The cooling side may be coupled to the array of protrusions (i.e., the cooling plate and the manifold plate may be coupled to the frame structure such that the protrusions touch the cooling side of the manifold plate, as has been described and illustrated). The distribution side may be configured to direct fluid entering the inlet to flow through the array of protrusions in a transverse direction that is substantially perpendicular to the longitudinal axis before being exiting the outlet. For example, the distribution side may include a barrier that, as has been illustrated and described, directs fluid to move up through long supply vents to then move laterally through the array of protrusions and to return through the manifold plate through long return vents.

The coupling of the cooler plate and the manifold plate to the frame structure may be performed in any suitable manner as may serve a particular implementation. For instance, these plates may be permanently or semi-permanently affixed within the frame structure by way of screws or other attachment devices, adhesive substances that hold the plates in place, mechanical means (e.g., flanges, ledges, shelves, tabs, detents, locating features, etc.) that secure the plates in particular ways within the frame structure, or the like.

A number of embodiments have been described. Nevertheless, it will be understood that various modifications may be made without departing from the spirit and scope of the specification.

It will also be understood that when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

The various apparatus and techniques described herein may be implemented using various semiconductor processing and/or packaging techniques. Some embodiments may be implemented using various types of semiconductor processing technologies associated with semiconductor substrates including, but not limited to, for example, Silicon (Si), Gallium Arsenide (GaAs), Silicon Carbide (SiC), and/or so forth.

It will also be understood that when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present.

Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

It will be understood that, although the terms first, second, etc. may be used herein to describe various elements, these elements should not be limited by these terms. These terms are only used to distinguish one element from another. A first element could be termed a second element, and, similarly, a second element could be termed a first element, without departing from the scope of the implementations of the disclosure. As used herein, the term and/or includes any and all combinations of one or more of the associated listed items.

While certain features of the described implementations have been illustrated as described herein, many modifications, substitutions, changes, and equivalents may occur to those skilled in the art. It is therefore to be understood that the appended claims are intended to cover such modifications and changes as fall within the scope of the implementations. It will be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components, and/or features of the different implementations described. As such, the scope of the present disclosure is not limited to the particular combinations hereafter claimed, but instead extends to encompass any combination of features or example implementations described herein irrespective of whether or not that particular combination has been specifically enumerated in the accompanying claims at this time.

What is claimed is:

1. A cooler assembly comprising:
an inlet;
an outlet;
a cooling channel including an array of protrusions configured to transfer heat from a plurality of electronic modules to fluid flowing through the array of protrusions, the plurality of electronic modules disposed along a longitudinal axis extending between the inlet and the outlet; and
a distribution channel in fluid communication with the cooling channel via a venting system, the distribution channel being configured to direct fluid entering at the inlet to flow through the cooling channel in a transverse direction substantially perpendicular to the longitudinal axis before exiting at the outlet.

2. The cooler assembly of claim 1, wherein:
the distribution channel includes a barrier between a supply side that includes the inlet and a return side that includes the outlet;
the venting system includes a supply vent network on the supply side of the barrier and a return vent network on the return side of the barrier, the supply vent network and the return vent network each extending a distance along the longitudinal axis that spans the plurality of electronic modules; and
the barrier is configured to direct fluid entering the inlet to flow to the outlet via the supply vent network, the cooling channel, and the return vent network.

3. The cooler assembly of claim 2, wherein a plurality of vents from the supply vent network and from the return vent network are interleaved such that the barrier between the supply side and the return side extends back and forth along the longitudinal axis in a zigzag pattern.

4. The cooler assembly of claim 1, wherein the distribution channel is configured to direct fluid to simultaneously flow through the cooling channel in both the transverse direction and in an additional transverse direction substantially perpendicular to the longitudinal axis and substantially opposite the transverse direction.

5. The cooler assembly of claim 1, wherein the distribution channel includes:
a barrier between a supply side that includes the inlet and a return side that includes the outlet; and
a set of flow control features on the return side of the barrier, the set of flow control features each configured to resist flow of fluid.

6. The cooler assembly of claim 5, wherein:
the plurality of electronic modules includes a first electronic module and a second electronic module each warranting a same amount of cooling; and
the set of flow control features is arranged to direct fluid to flow at an equivalent flow rate for the first electronic module and for the second electronic module.

7. The cooler assembly of claim 5, wherein:
the plurality of electronic modules includes a first electronic module and a second electronic module, the second electronic module warranting a different amount of cooling as the first electronic module; and
the set of flow control features is arranged to direct fluid to flow at different flow rates for the first electronic module and for the second electronic module.

8. The cooler assembly of claim 1, wherein the venting system includes a plurality of discrete slots disposed along the longitudinal axis and each aligned to the longitudinal axis.

9. The cooler assembly of claim 1, wherein the array of protrusions includes a series of planar fins disposed along the longitudinal axis and each aligned perpendicularly to the longitudinal axis to disallow flow of fluid along the longitudinal axis while allowing flow of fluid in the transverse direction.

10. The cooler assembly of claim 1, wherein the array of protrusions includes an array of discrete protrusions configured to allow flow of fluid along the longitudinal axis and in the transverse direction.

11. The cooler assembly of claim 10, wherein:
each discrete protrusion of the array of discrete protrusions has a rectangular shape, a rounded shape, or a wavy shape; and
the array of discrete protrusions is arranged in a grid pattern or a staggered grid pattern.

12. The cooler assembly of claim 1, wherein:
the cooler assembly is associated with a first pressure parameter and a first temperature parameter that respectively meet or improve upon a second pressure parameter and a second temperature parameter of a legacy cooler assembly; and
the cooler assembly is associated with a form factor equivalent to the legacy cooler assembly so as to function as a drop-in replacement for the legacy cooler assembly.

13. The cooler assembly of claim 1, wherein the plurality of electronic modules includes power electronics for a plurality of phases of a direct-current (DC) to alternating-current (AC) conversion circuit configured for use in an electric vehicle drivetrain.

14. A cooler assembly comprising:
a frame structure including an inlet and an outlet;
a cooler plate coupled to the frame structure and including a module side and a heatsink side, the module side being configured to host a plurality of electronic modules disposed along a longitudinal axis extending between the inlet and the outlet, the heatsink side including an array of protrusions configured to transfer heat from the plurality of electronic modules to fluid flowing through the array of protrusions; and
a manifold plate coupled to the frame structure and including a cooling side and a distribution side connected via a venting system that allows fluid communication through the manifold plate, the cooling side being coupled to the array of protrusions and the distribution side being configured to direct fluid entering the inlet to flow through the array of protrusions in a transverse direction that is substantially perpendicular to the longitudinal axis before exiting the outlet.

15. The cooler assembly of claim 14, wherein:
the distribution side of the manifold plate includes a barrier between a supply side that includes the inlet and a return side that includes the outlet;
the venting system includes a supply vent network on the supply side of the barrier and a return vent network on the return side of the barrier, the supply vent network and the return vent network each extending a distance along the longitudinal axis that spans the plurality of electronic modules; and
the barrier is configured to direct fluid entering the inlet to flow to the outlet via the supply vent network, the array of protrusions, and the return vent network.

16. The cooler assembly of claim 15, wherein a plurality of vents from the supply vent network and from the return vent network are interleaved such that the barrier between the supply side and the return side extends back and forth along the longitudinal axis in a zigzag pattern.

17. The cooler assembly of claim 14, wherein the distribution side of the manifold plate is configured to direct fluid to simultaneously flow through the array of protrusions in both the transverse direction and in an additional transverse direction substantially perpendicular to the longitudinal axis and substantially opposite the transverse direction.

18. The cooler assembly of claim 14, wherein the distribution side of the manifold plate includes:
a barrier between a supply side that includes the inlet and a return side that includes the outlet; and
a set of flow control features on the return side of the barrier, the set of flow control features each configured to resist flow of fluid.

19. A method comprising:
coupling a cooler plate with a frame structure that includes an inlet and an outlet, the cooler plate including a module side and a heatsink side, the module side being configured to host a plurality of electronic modules disposed along a longitudinal axis extending between the inlet and the outlet, the heatsink side including an array of protrusions configured to transfer heat from the plurality of electronic modules to fluid flowing through the array of protrusions; and
coupling a manifold plate with the frame structure, the manifold plate including a cooling side and a distribution side connected via a venting system that allows fluid communication through the manifold plate, the cooling side being coupled to the array of protrusions and the distribution side being configured to direct fluid entering the inlet to flow through the array of protrusions in a transverse direction that is substantially perpendicular to the longitudinal axis before being exiting the outlet.

20. The method of claim 19, further comprising coupling the plurality of electronic modules to the module side of the cooler plate.
